(19) United States
(12) Patent Application Publication
(10) Pub. No.: US 2009/0109636 A1
(43) Pub. Date: Apr. 30, 2009

(54) Multiple package module using a rigid flex printed circuit board

(75) Inventor: Shawn Arnold, Capitola, CA (US)

Correspondence Address: RAYMOND R. MOSER JR., ESQ.;MOSER IP LAW GROUP, 1030 BROAD STREET, 2ND FLOOR, SHREWSBURY, NJ, 07702, US

(73) Assignee: ChipStack, Inc.

(21) Appl. No.: 12/290,053

(22) Filed: Oct. 27, 2008

Related U.S. Application Data
(60) Provisional application No. 61/000,337, filed on Oct. 25, 2007.

(51) Int. Cl. H05K 7/00; H05K 3/00

(52) U.S. Cl. 361/728; 29/829

(57) ABSTRACT

A multiple package module and a method of fabricating a multiple package module. The module comprises a central region of a rigid flex circuit board for mounting circuitry, and at least one wing connected by a flexible portion to at least one edge of the central region of the rigid flex circuit board.

### CROSS-REFERENCE TO RELATED APPLICATIONS

This application claims benefit of U.S. Provisional Patent Application Ser. No. 61/000,337, filed Oct. 25, 2007, which is herein incorporated by reference.

### BACKGROUND OF THE INVENTION

1. Field of the Invention

Embodiments of the present invention generally relate to integrated circuit packaging and mounting and, more particularly, to multiple package modules (MPM) formed using a rigid flex printed circuit board.

2. Description of the Related Art

An important aspect of modern electronics packaging is increasing the component density. A compact packaging technology is needed when mounting area upon a circuit board is limited, dictating that circuit elements be closely spaced. Modules containing a number of semiconductor devices are used to densely place semiconductor devices (i.e., integrated circuits) and to obtain a small sized electronic device. In many applications, a large circuit board may be used within, for example, a consumer electronics device. A large circuit board may have many components that are custom designed for specific applications of the overall system. These custom applications require that the circuit board be custom designed for each of the applications. Such custom design of each circuit board for each particular application increases the cost of creating a line of products.

To reduce the cost of such applications, a multiple package module (MPM) may be used to contain the “heart” of the application, while support circuits for the key components of the MPM remain upon a generic circuit board, e.g., a mother board. The key components may be electrically sensitive, difficult to fabricate, a specified circuit and the like. The generic circuit board is used in all applications of the consumer electronic device and a custom MPM is designed for each specific application; thus, the overall electronic device is generic while the MPM provides the customization.

Although an MPM provides design flexibility, an MPM decreases the connection complexity. Mapping the various conductive traces from the MPM to the supporting circuit board can be tedious. Providing solder connections between the many traces and the supporting circuit board using conductive vias is prone to connection failure.

Therefore there is a need in the art for an improved multiple package module that reliably connects to a supporting circuit board.

### SUMMARY

A multiple package module and a method of fabricating a multiple package module. The module comprises a central region of a rigid flex circuit board for mounting circuitry, and at least one wing connected by a flexible portion to at least one edge of the central region of the rigid flex circuit board.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a top plan view of a first side of a frame in which a plurality of rigid flex modules are fabricated;

FIG. 2 depicts a bottom plan view of a second side of the frame of FIG. 1;

FIG. 3 depicts a single module within a frame having the wings folded into a mounting position;

FIG. 4 depicts a cross sectional side view of a single module having the wings folded into a mounting position;

FIG. 5 depicts a module of the present invention mounted to a support circuit board;

FIG. 6 depicts a side, cross-sectional view of another embodiment of the invention;

FIGS. 7 and 8 respectively depict a side cross-sectional view and a top plan view of another embodiment of the invention;

FIG. 9 depicts an alternative embodiment of the embodiment shown in FIGS. 7 and 8;

FIGS. 10A and 10B respectively depict a top plan view and a bottom plan view of another embodiment of the invention;

FIGS. 11A and 11B respectively depict a top plan view and a bottom plan view of another embodiment of the invention; and

FIGS. 12A and 12B respectively depict a top plan view and a bottom plan view of another embodiment of the invention.

### DETAILED DESCRIPTION

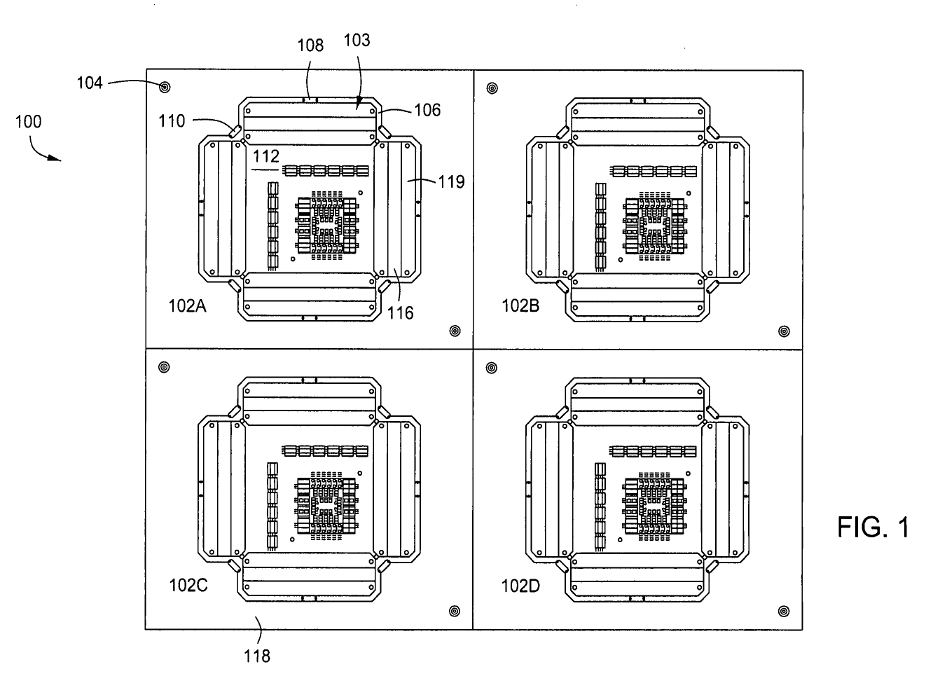

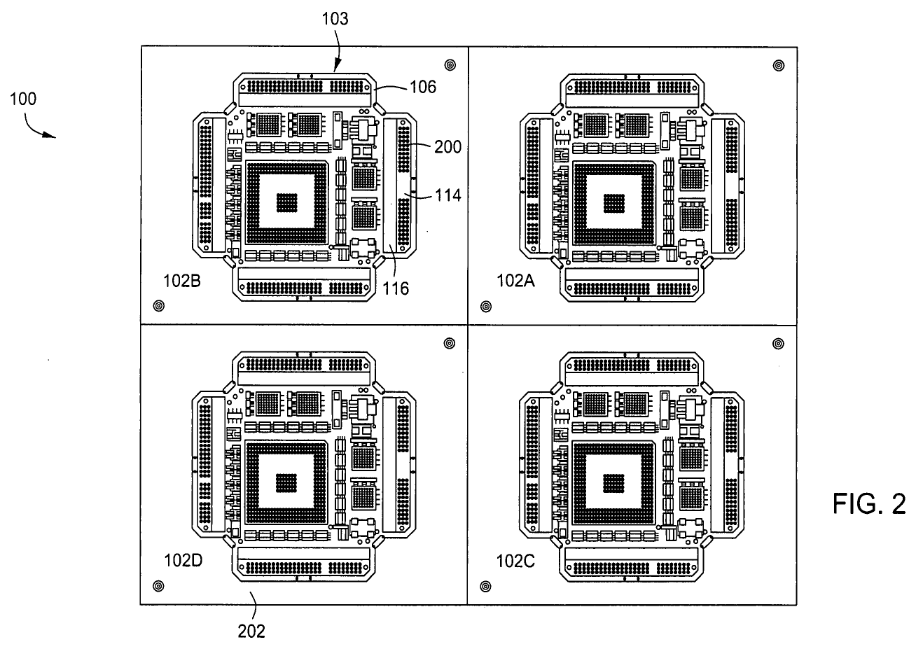

FIG. 1 depicts a top plan view of a first side 118 of a frame 100 within which a plurality of multiple package modules (MPM) rigid flex circuit boards 103 are fabricated. FIG. 2 depicts the second side 202 of the frame 100 comprising the plurality of rigid flex circuit boards for multiple package modules 103. To best understand the invention FIGS. 1 and 2 should be referred to simultaneously.

The frame 100 comprises a plurality of regions 102A, 102B, 102C, 102D wherein an MPM 103 is fabricated in a rigid flex circuit board. Apertures 104 are distributed upon each of the regions 102A, 102B, 102C, and 102D to facilitate alignment of individual circuits during assembly, test, rework. In one embodiment, the rigid flex circuit board can be fabricated in accordance with U.S. Pat. No. 5,499,444, entitled Method of Manufacturing a Rigid Flex Printed Circuit Board, issued Mar. 19, 1996, which is hereby incorporated by reference in its entirety. In another embodiment of the invention, the circuit board can be fabricated in accordance with commonly assigned U.S. patent application Ser. No. 11/895,922, filed Aug. 28, 2007, which is hereby incorporated by reference in its entirety. This application represents one method of fabricating a rigid flex circuit board, those skilled in the art will understand that other manufacturing techniques may be used.

The rigid flex circuit board comprises a region, for example, region 102A within which a circuit board 103 is formed. The board 103 comprises a central area 112 for mounting circuitry and at least one wing 114 that is connected to at least one edge of the central region 112 of the circuit board 103. The wing 114 is connected to the central region (a rigid portion of the circuit board) by a flexible portion 116. The at least one wing 114 comprises an array of solder bumps arranged in a ball grid array 200. The array 200 is formed on the top surface 202. As is described below, this array 200 facilitates reliable attachment of the MPM to a support circuit board. The pincut pattern may accept solder balls or utilize solder bumps for direct attach. The pattern defined is custom to the circuit due to the electrical properties required. This pattern is to match the base PCB (mother board).

The entire circuit board 103 is surrounded by a gap 106 that is routed into the frame 100 to define the outline of the circuit board 103. To retain the circuit board 103 within the frame 100, a plurality of bridges 108 and 110 are provided along the periphery of the circuit board 103. These bridges are perforated along their edges (also know as “mouse bites”) to facilitate snapping or breaking the bridge to detach the circuit board 103 from the frame 100. In an alternative embodiment, the bridges are scored along their edges to facilitate detachment of the circuit board 103 from the frame 100.

FIG. 1 depicts a first side 118 of the circuit board 103 containing mounting pads for circuitry on the “bottom” of the circuit board 103, while FIG. 2 depicts the top of the circuit board 103 comprising mounting pads for circuitry that is attached to the top surface. When mounted to a support circuit board (not shown), the top surface 202 (a first surface) is directed away from the support circuit board, while the bottom surface 118 (a second surface) is directed toward the support circuit board. In this manner, the module 103 of FIGS. 1 and 2 facilitate attaching circuitry including integrated circuits and support devices to both sides of the circuit board. The at least one wing 114, when folded under the board 103 defines a space that allows mounting of the circuit components beneath the circuit board 103. Once circuitry has been attached to the circuit boards 103 as they are held rigidly within the frame 100, the bridges 108, 110 can be detached or broken to enable the circuit board 103 to be removed from mounting.

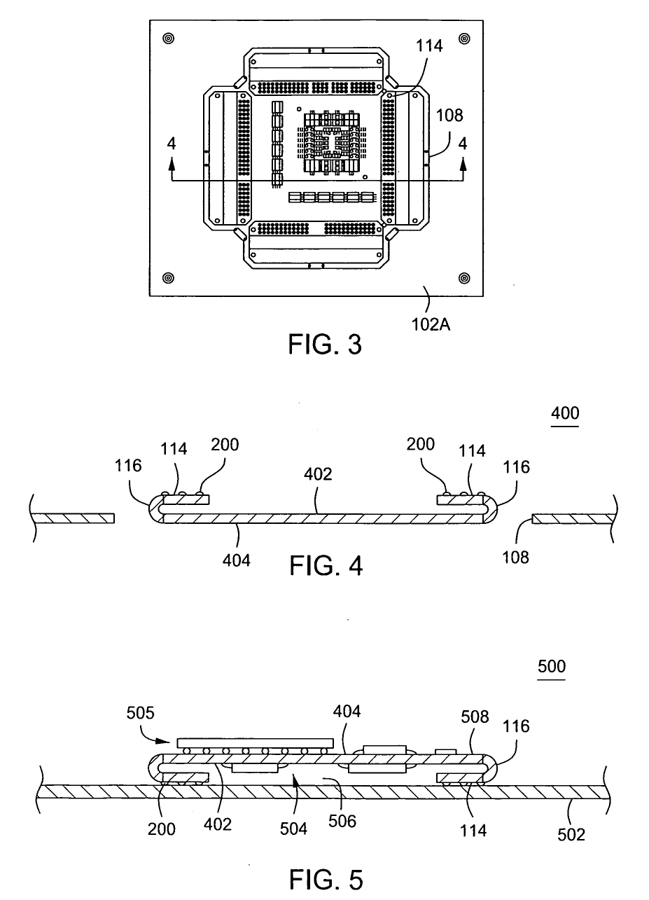

FIG. 3 depicts one region, for example, region 102A of the frame 100 of FIGS. 1 and 2. In FIG. 3, the bridges 108 have been detached to facilitate folding the at least one wing 114 inwardly to partially overlap the rigid portion 112 of the circuit board 103. The wing 114 comprises a plurality of solder bumps arranged in a ball grid to facilitate attaching the module to a circuit card.

FIG. 4 depicts a cross sectional view of FIG. 3 along lines 44 where a view of the folding operation of the wings 114 is shown. The top surface 402 of the circuit board 103 provides an area for attaching a plurality of circuit elements (e.g., components) and the bottom surface 404 provides another surface for attaching circuit elements. The wings 114 are folded along the flexible portion 116 to overlap the top 402 of the circuit board 103. The solder bumps 200 are formed and arranged to allow the circuit board 103 to be mounted to another circuit card (see FIG. 5).

FIG. 5 depicts an assembly 500 having the MPM 508 of one embodiment of the present invention mounted to a circuit board 502. Circuit elements 505 are attached to the “top” surface 404 of the MPM 508 and circuit elements 504 are attached to the “bottom” surface 402 of the MPM 508. The circuit elements 504 extend into a cavity 506 that is formed beneath the MPM 508 due to the wings 114 maintaining the MPM 508 module above the circuit board 502. The wings 114 comprise a ball grid 200 (or other form of conductive connection) that is attached and soldered in a conventional manner to the circuit 502. In this manner, the circuit board 502 can be a “generic” circuit board that is used in many devices, while the module provides a specific application electronics for a particular use of the electronic device.

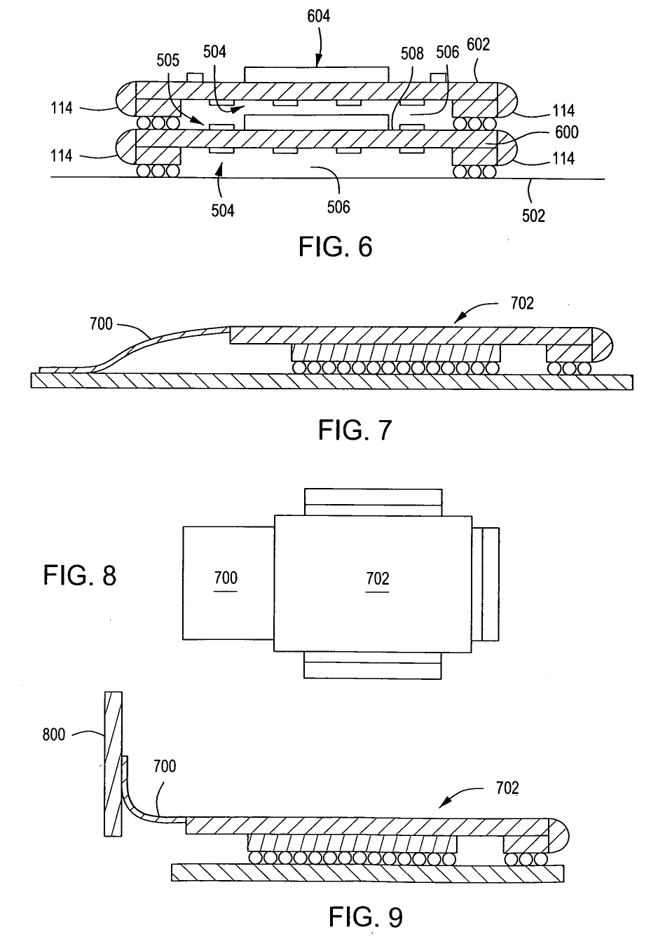

FIG. 6 depicts a side, cross-sectional view of another embodiment of the present invention. In this embodiment, the wings 114 of a first MPM 600 are bonded to a circuit board 502. A second MPM 602 has its wings 114 bonded to the top surface 508 of the first MPM 600. Such a structure is possible because the wings 114 of each MPM 600, 602 form a “cavity” 506 in which both the “bottom” circuits 504 of MPM 602 and the “top” circuits of MPM 600 reside. This structure could be extended to any number of MPMs within a stack 604. In some embodiments, MPM 600 may have “top” circuits 505 and MPM 602 may not have “bottom” circuits 504, or vice versa.

FIG. 7 depicts a side, cross-sectional view and FIG. 8 depicts a top plan view of another embodiment of the invention having one wing that extends as a “tail” 700. The tail 700 can be attached (bonded) to a circuit board without folding the tail beneath the MPM 702.

FIG. 9 depicts the embodiment of FIGS. 7 and 8 wherein the tail 700 is bonded to a separate circuit board 800. The second circuit board 800 may comprise a support circuit, display, and the like.

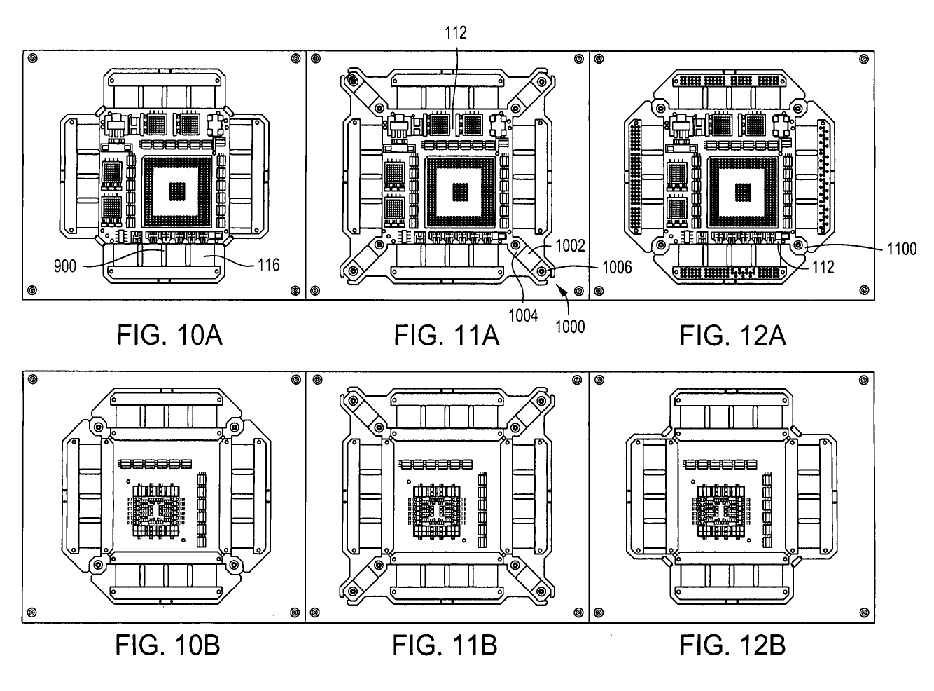

FIGS. 10A and 10B depict top and bottom plan views of another embodiment of the invention. To facilitate improved flexure of the embodiment of FIG. 1, at least one slot (a relief) 900 is formed in the flexible portion 116.

FIGS. 11A and 11B depict top and bottom plan views of another embodiment of the invention. To facilitate a “ruggedized” MPM, the standoffs 1000 are formed to have a flexible portion 1002 between a stand-off 1004 on the central region 112 and a distal stand-off 1006. The distal stand-off 1006 is folded beneath the stand-off 1004 to provide additional support for the MPM when bonded to a circuit board.

FIGS. 12A and 12B depict top and bottom plan views of another embodiment of the invention having circuit board stand-offs 1100 formed in the central region 112.

While the foregoing is directed to the illustrated embodiments of the present invention, other and further embodiments of the invention may be devised without departing from the basic scope thereof, and the scope thereof is determined by the claims that follow.

What is claimed is:

1. A multiple package module, comprising:
a central region of a rigid flex circuit board for mounting circuitry; and
at least one wing connected by a flexible portion to at least one edge of the central region of the rigid flex circuit board.

2. The apparatus of claim 1 wherein central region further comprises:
a first surface of the circuit board with circuitry mounting pads; and
a second surface of the circuit board with circuitry mounting pads.

3. The apparatus of claim 1 wherein the at least one wing extends as a tail.

4. The apparatus of claim 1 wherein the at least one wing comprises solder bumps arranged in a ball grid array.

5. The apparatus of claim 1 wherein the flexible portion comprises at least one slot.

6. The apparatus of claim 1 wherein the central region comprises at least one circuit board stand-off.

7. The apparatus of claim 1 wherein at least one flexible portion extends between a stand-off on the central region and a distal stand-off.

8. The apparatus of claim 7 wherein the distal stand-off is folded beneath the stand-off on the central region.

9. The apparatus of claim 8 wherein the central region is a rigid portion of the circuit board.

10. A method for fabricating at least one multiple package module, the method comprising:
routing a gap into a frame comprised of a rigid flex circuit board, wherein the gap defines an outline of a circuit board;
forming at least one wing connected to at least one edge of a central region of the circuit board, wherein the wing is connected to the central region by a flexible portion of the rigid flex circuit board; and
forming at least one bridge for retaining the circuit board within the frame.

11. The method of claim 10 further comprising:
forming the at least one slot in the flexible portion.

12. The method of claim 10 further comprising:
forming the at least one circuit board stand-off in the central region.

13. The method of claim 10 further comprising:
forming the at least one flexible portion between a stand-off on the central region and a distal stand-off.

14. The method of claim 10 further comprising:
forming circuitry mounting pads for circuitry on a first surface of the circuit board; and
forming circuitry mounting pads on a second surface of the circuit board.

15. The method of claim 10 further comprising forming solder bumps in a ball grid array on the at least one wing.

16. The method of claim 10 further comprising detaching of the circuit board from the frame facilitated by at least one bridge.

17. The method of claim 15 comprising folding the at least one wing along the flexible portion to overlap the central region of the circuit board.

18. Apparatus comprising:
a first multiple package module having a central region and a plurality of wings coupled to the central region by a flexible portion, wherein the plurality of wings are folded to be substantially parallel to the central region;
a second multiple package module having a second central region and a second plurality of wings coupled to the central region by a second flexible portion, where the plurality of wings are folded to be substantially parallel to the central, region and where the second plurality of wings are coupled to the central region of the first multiple package module.

19. The apparatus of claim 18 further comprising a standoff located between the central region and a wing in the plurality of wings to maintain the wing in a substantial parallel orientation with respect to the central region.

20. The apparatus of claim 18 wherein the first and second plurality of wings comprise ball grid arrays.
